(19) United States
(12) Patent Application Publication
(10) Pub. No.: US 2016/0172518 A1
(43) Pub. Date: Jun. 16, 2016

(54) REFLECTIVE MICROSTRUCTURED FILMS WITH MICROSTRUCTURES HAVING CURVED SURFACES, FOR USE IN SOLAR MODULES

(71) Applicant: 3M INNOVATIVE PROPERTIES COMPANY, Saint Paul, MN (US)

(72) Inventors: Jiaying Ma, Cottage Grove, MN (US); Roger J. Strharsky, Woodbury, MN (US)

(21) Appl. No.: 14/902,876

(22) PCT Filed: Jun. 26, 2014
(86) PCT No.: PCT/US2014/044344

§ 371 Date: Jan. 5, 2016

Related U.S. Application Data
(60) Provisional application No. 61/843,943, filed on Jul. 9, 2013.

(51) Int. Cl. H01L 31/056; G02B 19/00; G02B 5/08; H01L 31/0236

(52) U.S. Cl. CPC H01L 31/056; H01L 31/02366; G02B 19/0019; G02B 19/0042; G02B 5/0866

(57) ABSTRACT

Reflective microstructured films include a base layer, and an ordered arrangement of a plurality of microstructures projecting from the base layer. The microstructures have a cross section with at least two sides, at least one of these sides is a curved surface. Each curved surface is defined by an angle of curvature. Additionally, the microstructures include a reflective layer. These reflective microstructured films can be used in solar modules.

### FIELD OF THE DISCLOSURE

The present disclosure relates to reflective microstructured films with microstructured features that have curved surfaces, and their use in solar modules.

### BACKGROUND

Renewable energy is energy derived from natural resources that can be replenished, such as sunlight, wind, rain, tides, and geothermal heat. The demand for renewable energy has grown substantially with advances in technology and increases in global population. Although fossil fuels provide for the vast majority of energy consumption today, these fuels are non-renewable. The global dependence on these fossil fuels has not only raised concerns about their depletion but also environmental concerns associated with emissions that result from burning these fuels. As a result of these concerns, countries worldwide have been establishing initiatives to develop both large-scale and small-scale renewable energy resources. One of the promising energy resources today is sunlight. Globally, millions of households currently obtain power from solar photovoltaic systems. The rising demand for solar power has been accompanied by a rising demand for devices and materials capable of fulfilling the requirements for these applications.

Harnessing sunlight may be accomplished by the use of photovoltaic (PV) cells (solar cells), which are used for photoelectric conversion, e.g., silicon photovoltaic cells. PV cells are relatively small in size and typically combined into a physically integrated PV module (solar module) having a correspondingly greater power output. PV modules are generally formed from 2 or more “strings” of PV cells, with each string consisting of a plurality of cells arranged in a row and electrically connected in series using tinned flat copper wires (also known as electrical connectors, tabbing ribbons or bus wires). These electrical connectors are typically adhered to the PV cells by a soldering process.

PV modules typically comprise a PV cell surrounded by an encapsulant, such as generally described in U.S. Patent Publication No. 2008/0078445 (Patel et al). In some embodiments, the PV module includes encapsulant on both sides of the PV cell. Two panels of glass (or other suitable polymeric material) are positioned adjacent and bonded to the front-side and backside of the encapsulant. The two panels are transparent to solar radiation and are typically referred to as front-side layer and backside layer, or backsheet. The front-side layer and the backsheet may be made of the same or a different material. The encapsulant is a light-transparent polymer material that encapsulates the PV cells and also is bonded to the front-side layer and backsheet so as to physically seal off the cells. This laminated construction provides mechanical support for the cells and also protects them against damage due to environmental factors such as wind, snow, and ice. The PV module is typically fit into a metal frame, with a sealant covering the edges of the module engaged by the metal frame. The metal frame protects the edges of the module, provides additional mechanical strength, and facilitates combining it with other modules so as to form a larger array or solar panel that can be mounted to a suitable support that holds the modules at the proper angle to maximize reception of solar radiation.

The art of making photovoltaic cells and combining them to make laminated modules is exemplified by the following U.S. Pat. Nos. 4,751,191 (Gonsiorawski et al.); 5,074,920 (Gonsiorawski et al.), 5,118,362 (St. Angelo et al.); 5,178,685 (Borenstein et al.); 5,320,684 (Amick et al); and 5,478,402 (Hanoka).

### SUMMARY

Described herein are reflective microstructured films with microstructured features that have one or more curved surfaces, solar modules prepared from these reflective microstructured films, and methods of preparing solar modules.

In some embodiments, the reflective film comprises a base layer, and an ordered arrangement of a plurality of microstructures projecting from the base layer. The microstructures have a cross section comprising at least two sides wherein at least one of the at least two sides comprises a curved surface defined by an angle of curvature. Additionally, the microstructures comprise a reflective layer.

Also described herein are solar modules. In some embodiments, the solar modules comprise a plurality of solar cells, and a reflective film, where the reflective film has been described above.

Additionally, methods for preparing solar modules are described. The methods comprise providing a reflective film, providing a plurality of solar cells arranged on a support substrate and connected by tabbing ribbons, attaching the reflecting film to the solar cells and adjacent areas, and attaching a transparent cover layer over the reflecting film. The reflective films have been described above.

### BRIEF DESCRIPTION OF THE DRAWINGS

The present application may be more completely understood in consideration of the following detailed description of various embodiments of the disclosure in connection with the accompanying drawings.

FIG. 1 shows a cross sectional of a structured reflective film of an embodiment of this disclosure.

FIG. 2 shows a cross sectional view of the surface of a microstructured element of a prior art structured reflective film.

FIG. 3 shows a cross sectional view of the surface of a microstructured element of a structured reflective film of an embodiment of this disclosure.

FIG. 4 shows a ray tracing of the reflection pattern from the surface of a microstructured element of a prior art structured reflective film.

FIG. 5 shows a ray tracing of the reflection pattern from the surface of a microstructured element of a structured reflective film of an embodiment of this disclosure.

In the following description of the illustrated embodiments, reference is made to the accompanying drawings, in which is shown by way of illustration, various embodiments in which the disclosure may be practiced. It is to be understood that the embodiments may be utilized and structural changes may be made without departing from the scope of the present disclosure. The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

Solar modules generally are prepared as laminated arrays of photovoltaic solar cells. The array is generally between a support layer that is generally clear, such as glass or a transparent polymeric material and a cover layer that is also generally transparent and may be the same material as the support layer or it may be different. Because the solar cells themselves are fairly small and cover only part of the total surface area of the module, a variety of techniques have been developed to direct more sunlight onto the solar cell and thus increase the efficiency of the module. In one technique, described in U.S. Pat. No. 4,235,643 (Amick) an optical medium having a plurality of light-reflective facets is disposed between adjacent cells. The light-reflective facets are angularly disposed so as to define a plurality of grooves with the angle at the vertex formed by two mutually converging facets being between 110° to 130°, preferably about 120°. The result of these facets is that light impinging on the facets will be reflected back into the transparent front cover member at an angle greater than the critical angle, and is then reflected again internally from the front surface of the cover member so as to impinge on the solar cells. In U.S. Pat. No. 5,994,641 (Kardauskas), a flexible reflector means is used as the optical medium having a plurality of grooves. The flexible reflector means is an optically reflective sheet material with a coating of reflective metal such as silver or aluminum. The facets of the reflective sheet material have straight sides and sharp peaks.

In this disclosure, reflective films (sometimes referred as light directing mediums) useful in solar modules are described. Such reflective films have a generally planar back surface and a structured front surface. The structured front surface comprises an array of microstructures having at least one curved surface. These microstructures may be viewed as prisms, where these prisms have, in a cross sectional view, at least two sides. In prisms, these sides or surfaces when viewed in a cross sectional view are sometimes called “facets”. Because facets are generally described as being planar or flat, in this disclosure the terms “sides” or “surfaces” are generally used to describe the sides of the microstructures, but these terms can be used interchangeably with facets. These reflective films with microstructures having at least one curved side have a variety of advantages over the reflective films with microstructures that comprise straight-line or non-curved sides or facets that have been previously described and used. In addition, the peaks of the microstructures may be sharp or rounded, the advantages of rounded peaks is described in the copending application Attorney Docket Number 61499 titled “Reflecting Films With Curved Microstructures For Use In Solar Modules” filed on the same day as the present application.

A variety of advantages are gained by the microstructures having at least one curved side. The microstructures with at least one curved side, in contrast to microstructures having straight-line sides or facets or essentially straight-line sides or facets, have the ability to spread out light. This advantage will be described in greater detail below.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein. The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. For example, reference to “a layer” encompasses embodiments having one, two or more layers. As used in this specification and the appended claims, the term “or” is generally employed in its sense including “and/or” unless the content clearly dictates otherwise.

As used herein, the term “ordered arrangement” when used to describe microstructural features, especially a plurality of microstructures, means an imparted pattern different from natural surface roughness or other natural features, where the arrangement can be continuous or discontinuous, can be a repeating pattern, a non-repeating pattern, a random pattern, etc.

As used herein, the term “microstructure” means the configuration of features wherein at least 2 dimensions of the features are microscopic. The topical and/or cross-sectional view of the features must be microscopic.

As used herein, the term “microscopic” refers to features of small enough dimension so as to require an optic aid to the naked eye when viewed from any plane of view to determine its shape. One criterion is found in Modem Optic Engineering by W. J. Smith, McGraw-Hill, 1966, pages 104-105 whereby visual acuity, “. . . is defined and measured in terms of the angular size of the smallest character that can be recognized.” Normal visual acuity is considered to be when the smallest recognizable letter subtends an angular height of 5 minutes of arc on the retina. At a typical working distance of 250 mm (10 inches), this yields a lateral dimension of 0.36 mm (0.0145 inch) for this object.

The term “(meth)acrylate” refers to monomeric acrylic or methacrylic esters of alcohols. Acrylate and methacrylate monomers or oligomers are referred to collectively herein as “(meth)acrylates”. Polymers described as “(meth)acrylate-based” are polymers or copolymers prepared primarily (greater than 50% by weight) from (meth)acrylate monomers and may include additional ethylenically unsaturated monomers.

Unless otherwise indicated, “optically transparent” refers to an article, film or adhesive composition that has a high light transmittance over at least a portion of the visible light spectrum (about 400 to about 700 nm).

The term “adjacent” as used herein when referring to two layers means that the two layers are in proximity with one another with no intervening open space between them. They may be in direct contact with one another (e.g. laminated together) or there may be intervening layers.

As used herein the term “critical angle” refers to the largest value which the angle of incidence may have for a ray of light passing from a more dense optical medium to a less dense optical medium. If the angle of incidence exceeds the critical angle, the ray of light will not enter the less dense medium but will be totally internally reflected back into the denser medium.

Disclosed herein are reflective films suitable for use in preparing solar modules.

These films comprise a base layer, and an ordered arrangement of a plurality of microstructures projecting from the base layer, the microstructures having a cross section comprising at least two sides wherein at least one of the sides comprises a curved surface, and wherein the microstructures comprise a reflective layer.

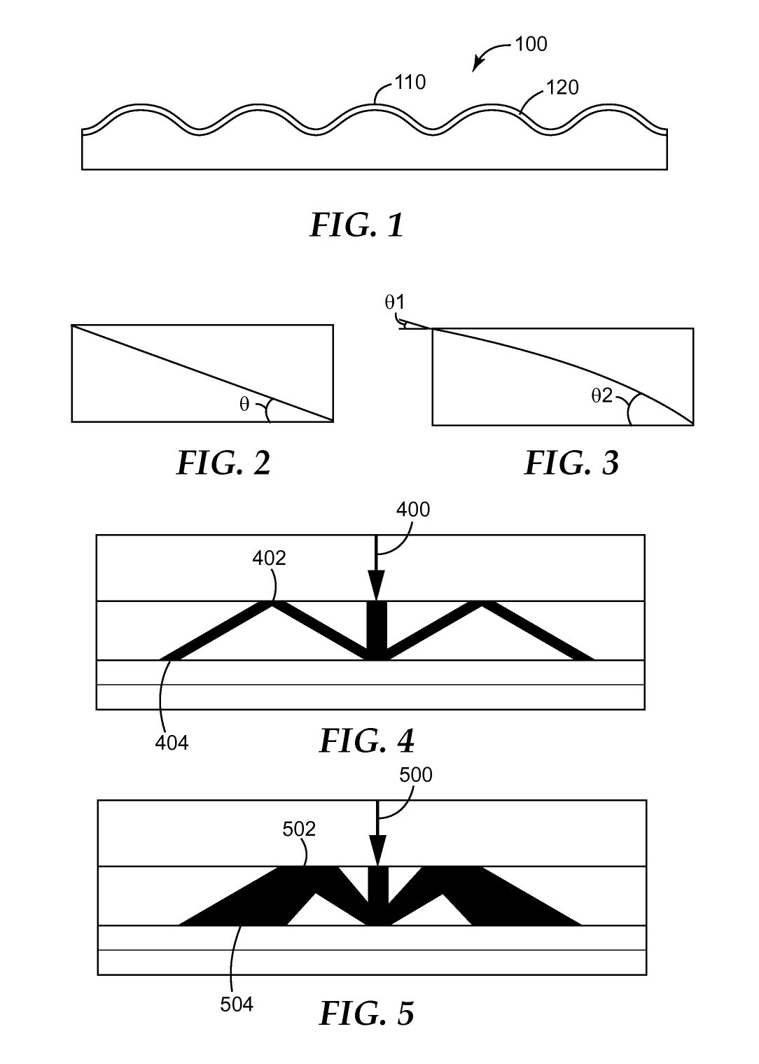

FIG. 1 shows a cross sectional view of a microstructured reflective film of the present disclosure. In FIG. 1, Reflective film 100 contains microstructured features 110, which have curved surfaces, and contain reflective layer 120. Typically, reflective layer 120 is a reflective metal coating layer comprising silver or aluminum, more typically aluminum for cost reasons. The microstructures protrude 5 micrometers to 500 micrometers from the base layer.

The microstructures can be described as having an angle of curvature. In some embodiments, such as the one shown in FIG. 1, the angle of the curvature is the same for all of the curved surfaces. This is not necessarily the case in all embodiments. This angle of curvature is explained in FIGS. 2 and 3. FIG. 3 shows a cross sectional view of a portion of one structure from film 100 of FIG. 1. FIG. 2 shows a cross sectional view of a portion of one structure from a film where the sides of the structures do not have curvature. Angle θ in FIG. 2 is compared to angles θ1 and θ2 of FIG. 3. FIG. 2 is able to be defined by a single angle θ, because the side shown in FIG. 2 is a straight line (if angles θ1 and θ2 were drawn in FIG. 2, these angles would be the same, thus rather than two angles, a single angle θ completely defines FIG. 2). In FIG. 3, the angles θ1 and θ2 are different because the side shown in FIG. 3 is curved. The angular width of a curved line with a constant radius of curvature is the difference θ1−θ2, which herein is referred to as the angle of curvature. Parallel rays of light reflected from such a surface spread into a fan of rays with an angular width equal to twice the angle of curvature. It thus becomes clear that the angle of curvature in FIG. 2 is 0° because, as described above, if angles θ1 and θ2 were shown in FIG. 2 they would be the same (angle θ) and thus the difference is zero. In films of this disclosure, the angle of curvature is greater than 0° and less than or equal to 9°.

The effect of this angle of curvature is shown in FIGS. 4 and 5 which are ray tracings prepared using commercially available software called TracePro. FIG. 4 corresponds to a ray tracing of microstructured surface with an angle of curvature of 0° (such as is shown in FIG. 2). In FIG. 4, incident light 400 is reflected from the microstructured surface and contacts the glass cover layer 402 and is reflected by total internal reflection to the surface of the solar cell at 404. FIG. 4 shows that the zone of contact of the reflected light with the solar cell is very narrow. FIG. 5 corresponds to a ray tracing of microstructured surface with an angle of curvature of 9°. In FIG. 5, incident light 500 is reflected from the microstructured surface and contacts the glass cover layer 502 and is reflected by total internal reflection to the surface of the solar cell at 504. FIG. 5 shows that the zone of contact of the reflected light with the solar cell is very broad, much broader than the zone of contact in FIG. 4. In the embodiments used to prepare this modeling data, the cover layer (402 or 502) was glass. Other embodiments are also possible where different materials are used for this cover layer. In these embodiments, the range of suitable angle of curvature values may be somewhat different, as different cover layer materials have different critical angles, and thus will reflect differently.

The broadened zone of contact of reflected light produced by microstructures with curved surfaces is beneficial for use in solar modules, because narrow zones of contact of reflected light with solar cells can produce “hot spots” or “hot lines”. These hot spots or hot lines are detrimental because concentrating too much light on a narrow spot or line can make the solar cell less efficient than if the reflected light is more spread out and contacts the solar cell at a broader zone of contact. In extreme cases, concentrated light can even damage the solar cell. As can be seen in FIGS. 4 and 5, the zone of contact 504 is much broader in FIG. 5 than the zone of contact 404 in FIG. 4.

As mentioned above, the reflecting film of this disclosure comprises a base layer, and an ordered arrangement of a plurality of microstructures projecting from the base layer, the microstructures having a cross section comprising at least two sides wherein at least one of the sides comprises a curved surface, and wherein the microstructures comprise a reflective layer. The base layer material comprises a polymeric material. A wide range of polymeric materials are suitable for preparing the base layer. Examples of suitable polymeric materials include cellulose acetate butyrate; cellulose acetate propionate; cellulose triacetate; poly(meth)acrylates such as polymethyl methacrylate; polyesters such as polyethylene terephthalate, and polyethylene naphthalate; copolymers or blends based on naphthalene dicarboxylic acids; polyether sulfones; polyurethanes; polycarbonates; polyvinyl chloride; syndiotactic polystyrene; cyclic olefin copolymers; silicone-based materials; and polyolefins including polyethylene and polypropylene; and blends thereof. Particularly suitable polymeric materials for the base layer are polyolefins and polyesters.

Typically, the microstructures also comprise a polymeric material. In some embodiments, the polymeric material of the microstructures is the same composition as the base layer. In other embodiments, the polymeric material of the microstructures is different from that of the base layer. In some embodiments, the base material layer is a polyester and the microstructured material is a poly(meth)acrylate.

In some embodiments, the microstructured film is prepared by imparting microstructures onto a film. In these embodiments, the base layer and the microstructures comprise the same polymeric composition. In other embodiments, the layer of microstructures is prepared separately and laminated to the base layer. This lamination can be done using heat, a combination of heat and pressure, or through the use of an adhesive. In still other embodiments, the microstructures are formed on the base layer.

The microstructured film or a layer of microstructures may be prepared by embossing. In this process, a flat film with an embossable surface is contacted to a structured tool with the application of pressure and/or heat to form an embossed surface. The entire flat film may comprise an embossable material, or the flat film may only have an embossable surface. The embossable surface may comprise a layer of a material that is different from the material of the flat film, that is to say that the flat film may have a coating of embossable material at its surface. The embossed surface is a structured surface. The structure on the embossed surface is the inverse of structure on the tool surface, that is to say a protrusion on the tool surface will form a depression on the embossed surface, and a depression on the tool surface will form a protrusion on the embossed surface. The microstructural features may assume a variety of shapes. FIG. 1 shows rounded peaks, but a wide variety of other shapes are also possible.

Typically, the microstructured tool is a molding tool. Structured molding tools can be in the form of a planar stamping press, a flexible or inflexible belt, or a roller. Furthermore, molding tools are generally considered to be tools from which the microstructured pattern is generated in the surface by embossing, coating, casting, or platen pressing and do not become part of the finished article.

A broad range of methods are known to those skilled in this art for generating microstructured molding tools. Examples of these methods include but are not limited to photolithography, etching, discharge machining, ion milling, micromachining, and electroforming. Microstructured molding tools can also be prepared by replicating various microstructured surfaces, including irregular shapes and patterns, with a moldable material such as those selected from the group consisting of crosslinkable liquid silicone rubber, radiation curable urethanes, etc. or replicating various microstructures by electroforming to generate a negative or positive replica intermediate or final embossing tool mold. Also, microstructured molds having random and irregular shapes and patterns can be generated by chemical etching, sandblasting, shot peening or sinking discrete structured particles in a moldable material. Additionally any of the microstructured molding tools can be altered or modified according to the procedure taught in U.S. Pat. No. 5,122,902 (Benson). The tools may be prepared from a wide range of materials including metals such as nickel, copper, steel, or metal alloys, or polymeric materials.

In this way the base layer and the microstructured layer are a single construction and are thus made from the same material. There are also several methods for generating a microstructured layer without the microstructured layer being part of the base layer. For example, a curable or molten polymeric material could be cast against the microstructured molding tool and allowed to cure or cool to form a microstructured layer in the mold. This layer, in the mold, could then be adhered to a polymeric film, either through heat and/or pressure or through the use of an adhesive such as a pressure sensitive adhesive or curable adhesive. The molding tool could then be removed to generate the construction with a base layer and a microstructured layer. In a variation of this process, the molten or curable polymeric material in the microstructured molding tool could be contacted to a film and then cured or cooled. In the process of curing or cooling the polymeric material in the molding tool can adhere to the film. Upon removal of the molding tool, the construction is formed comprising a base layer (the film) and a microstructured layer. In some embodiments, the microstructured layer is prepared from a radiation curable (meth)acrylate material, and the molded (meth)acrylate material is cured by exposure to actinic radiation.

Also disclosed herein are solar modules. These solar modules comprise a plurality of solar cells, and a reflective film comprising a plurality of microstructures projecting from a base layer, the microstructures having a cross section comprising at least two sides wherein at least one of the sides comprises a curved surface, and comprising a reflective layer. The reflective films have been described above. The array of solar cells is generally between a support layer that is generally clear, such as glass or a transparent polymeric material and a cover layer that is also generally transparent and may be the same material as the support layer or it may be different.

Also disclosed herein are methods of preparing solar modules. These methods include providing a reflective film, the reflective film comprising a plurality of microstructures projecting from a base layer, the microstructures having a cross section comprising at least two sides wherein at least one of the sides comprises a curved surface, and comprising a reflective layer, providing a plurality of solar cells arranged on a support substrate and connected by tabbing ribbons, attaching the reflecting film to the solar cells and adjacent areas, and attaching a transparent cover layer over the reflecting film. The reflective film is described above.

In some embodiments, the reflective film is placed adjacent to the tabbing ribbons.

The tabbing ribbons (electrical connectors) create shaded areas that are inactive, that is to say that light impinging onto these areas is not used for photovoltaic conversion. Placement of reflective film adjacent to these tabbing ribbons can thus increase the energy generated by the solar module, as is discussed in US Patent Attorney Docket No. 69734US002 filed Mar. 27, 2013.

What is claimed is:

1. A reflective film comprising:
a base layer; and
an ordered arrangement of a plurality of microstructures projecting from the base layer,
the microstructures having a cross section comprising at least two sides, wherein at
least one of the sides comprises a curved surface defined by an angle of curvature, and
wherein the microstructures comprise a reflective layer.

2. The reflective film of claim 1, wherein the microstructures protrude 5 micrometers to 500 micrometers from the base layer.

3. The reflective film of claim 1, wherein all of the at least two sides comprise curved surfaces, and wherein the angle of curvature of the curved surfaces is the same.

4. The reflective film of claim 1, wherein the angle of curvature is greater than 0° and less than or equal to 9°.

5. The reflective film of claim 1, wherein the base layer comprises a polymeric layer.

6. The reflective film of claim 1, wherein the microstructures comprise a polymeric material.

7. The reflective film of claim 6, wherein the microstructures comprise the same polymeric material as the base layer.

8. The reflective film of claim 6, wherein the microstructures comprise a different polymeric from the base layer.

9. The reflective film of claim 1, wherein the reflective layer comprises a metallic coating.

10. The reflective film of claim 9, wherein the metallic coating comprises aluminum, silver, or a combination thereof.

11. The reflective film of claim 1, wherein the peaks of the microstructures are rounded.

12. A solar module comprising:
a plurality of solar cells; and
a reflective film, the reflective film comprising:
a base layer; and
an ordered arrangement of a plurality of microstructures projecting from the base layer, the microstructures having a cross section comprising at least two sides wherein at least one of the sides comprises a curved surface defined by an
angle of curvature, and wherein the microstructures comprise a reflective layer.

13. The solar module of claim 12, wherein the microstructures protrude 5 micrometers to 500 micrometers from the base layer.

14. The solar module of claim 12, wherein the angle of curvature is greater than 0° and less than or equal to 9°.

15. The solar module of claim 12, wherein the reflective layer comprises a metallic coating.

16. The solar module of claim 12, wherein the reflective film is located adjacent to the solar cells and/or adjacent to tabbing ribbons connecting the solar cells.

17. A method of preparing a solar module comprising:
providing a reflective film, the reflective film comprising:
a base layer; and
an ordered arrangement of a plurality of microstructures projecting from the base layer, the microstructures having a cross section comprising at least two
sides wherein at least one of the sides comprises a curved surface defined by an
angle of curvature, and wherein the microstructures comprise a reflective layer;
providing a plurality of solar cells arranged on a support substrate and connected by tabbing ribbons;
attaching the reflecting film to the solar cells and/or adjacent areas; and
attaching a transparent cover layer over the reflecting film.

18. The method of claim 17, wherein the microstructures protrude 5 micrometers to 500 micrometers from the base layer.

19. The method of claim 17, wherein the angle of curvature is greater than 0° and less than or equal to 9°.

20. The method of claim 17, wherein the reflective layer comprises a metallic coating.

21. The method of claim 20, wherein the metallic coating comprises aluminum, silver, or a combination thereof.

22. The method of claim 17, wherein the peaks of the microstructures are rounded.

23. The method of claim 17, wherein the reflecting film is attached adjacent to at least a portion of the tabbing ribbons.
